(19) United States
(12) Patent Application Publication
(10) Pub. No.: US 2025/0137777 A1
(43) Pub. Date: May 1, 2025

(54) METHOD OF MANUFACTURING SEMICONDUCTOR DEVICE

(71) Applicant: FUJI ELECTRIC CO., LTD., Kawasaki-shi (JP)

(72) Inventors: Shunya HAYASHIDA, Matsumoto-city (JP); Naoko KODAMA, Matsumoto-city (JP); Kazuhiro KITAHARA, Matsumoto-city (JP); Tatsuya HASHIMOTO, Azumino-city (JP); Noriaki NOJI, Nagano-city (JP); Ryota KATAOKA, Matsumoto-city (JP)

(73) Assignee: FUJI ELECTRIC CO., LTD., Kawasaki-shi (JP)

(21) Appl. No.: 18/819,703

(22) Filed: Aug. 29, 2024

(30) Foreign Application Priority Data
Oct. 25, 2023 (JP) 2023-183593

(51) Int. Cl. G01B 11/30; H01L 21/3205; H01L 21/3213; H01L 21/66

(52) U.S. Cl. CPC G01B 11/30; H01L 21/32051; H01L 21/32139; H01L 22/26; G01B 2210/56

(57) ABSTRACT

A resist film formed on a surface electrode is exposed and developed, thereby forming a fine resist pattern. An exposure focus is aligned with a surface of the resist film on a normal portion of the surface electrode, whereby deficient pattern portions of the resist pattern are caused on a convex defect and on a concave defect of the surface electrode. The deficient pattern portions of the resist pattern are detected either using a difference of intensities of lights reflected from the resist pattern on the surface electrode between an area thereof where the deficient pattern portion is formed and an area thereof where no surface defect occurs by irradiating light on the resist pattern, or using a comparison between a surface image of deficient pattern portion and a surface image of the surface where no surface defect occurs by photographing the surface of the semiconductor wafer.

### CROSS REFERENCE TO RELATED APPLICATIONS

This application is based upon and claims the benefit of priority of the prior Japanese Patent Application No. 2023-183593, filed on Oct. 25, 2023, the entire contents of which are incorporated herein by reference.

### BACKGROUND OF THE INVENTION

### 1. Field of the Invention

Embodiments of the disclosure relate to a method of manufacturing a semiconductor device.

### 2. Description of the Related Art

Conventionally, one known inspection method involves irradiating laser light on a semiconductor wafer and detecting foreign matter on a surface of the semiconductor wafer based on an intensity ratio of reflected scattered light (for example, refer to Japanese Laid-Open Patent Publication No. H9-115973).

### SUMMARY OF THE INVENTION

According to an embodiment of the present disclosure, a method of manufacturing a semiconductor device, the method includes: as a first process, preparing a semiconductor wafer and forming a surface electrode on a surface of the semiconductor wafer; as a second process, forming a resist film on the surface electrode; as third process, exposing and developing the resist film, thereby forming a resist pattern on the surface electrode; and as a fourth process, detecting a surface defect occurring in the surface electrode during the first process, either using a difference of intensities of lights reflected from the resist pattern on the surface electrode between an area thereof where the surface defect occurs and an area thereof where no surface defect occurs by irradiating light on the resist pattern on the surface electrode, or using a comparison between a surface image of the area where the surface defect occurs and a surface image of the surface where no surface defect occurs by photographing the surface of the semiconductor wafer using a photographing mechanism. The third process includes causing a deficient pattern portion to occur in a portion of the resist pattern at the surface defect. The fourth process includes detecting a position of the deficient pattern portion at the resist pattern as a focal point of the lights irradiated or a focal point of the photographing mechanism, and determining a detected position of the deficient pattern portion as a detection position of the surface defect.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a flowchart showing an outline of a method of manufacturing a semiconductor device according to an embodiment.

FIG. 2 is a plan view depicting a state when a semiconductor wafer is viewed from front side thereof.

FIG. 3 is a cross-sectional view depicting a state of the semiconductor device according to the embodiment during manufacture.

FIG. 4 is a cross-sectional view depicting a state of the semiconductor device according to the embodiment during manufacture.

FIG. 5 is a cross-sectional view depicting a state of the semiconductor device according to the embodiment during manufacture.

FIG. 6 is a cross-sectional view depicting a state of the semiconductor device according to the embodiment during manufacture.

FIG. 7A is a cross-sectional view depicting a state of the semiconductor device according to the embodiment during manufacture.

FIG. 7B is a cross-sectional view depicting a state of the semiconductor device according to the embodiment during manufacture.

FIG. 7C is a cross-sectional view depicting a state of the semiconductor device according to the embodiment during manufacture.

FIG. 8A is a cross-sectional view depicting a state of the semiconductor device according to the embodiment during manufacture.

FIG. 8B is a cross-sectional view depicting a state of the semiconductor device according to the embodiment during manufacture.

FIG. 8C is a cross-sectional view depicting a state of the semiconductor device according to the embodiment during manufacture.

FIG. 8D is a cross-sectional view depicting a state of the semiconductor device according to the embodiment during manufacture.

FIG. 9 is a plan view depicting an example of a resist pattern at step S6 in FIG. 1.

FIG. 10 is a plan view depicting an example of the resist pattern at step S6 in FIG. 1.

FIG. 11 is a plan view depicting an example of the resist pattern at step S6 in FIG. 1.

FIG. 12 is a plan view depicting an example of the resist pattern at step S6 in FIG. 1.

FIG. 13A is a cross-sectional view depicting a state of the semiconductor device according to the embodiment during manufacture.

FIG. 13B is a cross-sectional view depicting a state of the semiconductor device according to the embodiment during manufacture.

FIG. 14A is a cross-sectional view depicting a state of a semiconductor device of a reference example during manufacture.

FIG. 14B is a cross-sectional view depicting a state of the semiconductor device of a reference example during manufacture.

FIG. 15 is a cross-sectional view depicting an example of a structure of a semiconductor device manufactured by adopting the method of manufacturing the semiconductor device according to the embodiment.

FIG. 16 is a cross-sectional view schematically depicting a state of the semiconductor device of the reference example during manufacture.

FIG. 17 is a cross-sectional view schematically depicting a state of the semiconductor device of the reference example during manufacture.

FIG. 18 is a cross-sectional view schematically depicting a state of the semiconductor device of the reference example during manufacture.

FIG. 19 is a cross-sectional view schematically depicting a state of the semiconductor device of the reference example during manufacture.

FIG. 20A is a diagram schematically depicting a state of a convex defect of a surface electrode at a time of inspection.

FIG. 20B is a diagram schematically depicting a state of the convex defect of the surface electrode at the time of inspection.

FIG. 20C is a diagram schematically depicting a state of the convex defect of the surface electrode at the time of inspection.

FIG. 21A is a diagram schematically depicting a state of grain boundaries of the surface electrode at a time of inspection.

FIG. 21B is a diagram schematically depicting a state of the grain boundaries of the surface electrode at the time of inspection.

FIG. 21C is a diagram schematically depicting a state of the grain boundaries of the surface electrode at the time of inspection.

### DETAILED DESCRIPTION OF THE INVENTION

First, problems associated with the conventional techniques are discussed. When foreign matter is adhered to the surface of a semiconductor wafer during formation of a surface electrode, a defect caused by the foreign matter occurs at the surface of the surface electrode. In a conventional method of inspection, automated visual inspection by a visual inspection system falsely detects grain boundaries (grains) as defects of another defect type and thus, re-evaluation by visual inspection by a site-operator is performed thereafter, whereby throughput diminishes.

An overview of an embodiment of the present disclosure is described. (1) A method of manufacturing a semiconductor device according to one embodiment of the present disclosure is as follows. A first process of forming a surface electrode on a surface of a semiconductor wafer is performed. A second process of forming a resist film on the surface electrode is performed. A third process of exposing and developing the resist film and thereby, forming a predetermined resist pattern is performed. A fourth process of detecting a surface defect generated on the surface electrode during the first process is performed, the surface defect being detected based on an intensity ratio of the reflected light of the light irradiated on the semiconductor wafer or by photographing the surface of the semiconductor wafer using a photographing mechanism (the surface where the surface electrode is formed) and comparing images. In the third process, a deficient pattern portion is caused to occur at the portion of the resist pattern on the surface defect. In the fourth process, the surface of the resist pattern is set as a focal point of the photographing mechanism or the irradiated light, the deficient pattern portion is detected, and a detection position of the deficient pattern portion is set as a detection position of the surface defect.

According to the disclosure above, during the fourth process, the focal point of the imaging mechanism or the irradiated light of the visual inspection system is not aligned with the grain boundaries of the surface electrode and thus, false detection of the grain boundaries of the surface electrode by the visual inspection system does not occur. Defects detected by the visual inspection system need not be re-evaluated by a site-operator and thus, labor for the re-evaluation by a manual visual inspection performed by a site-operator may be reduced.
(2) Further, in the method of manufacturing the semiconductor device according to the present disclosure, in (1) above, in the third process, resist left in the deficient pattern portion may have a wider width than a width of the resist left on a normal portion of the surface electrode free of the surface defect, or the resist removed in the deficient pattern portion may have a wider width than a width of through-holes of the resist on the normal portion of the surface electrode. According to the disclosure above, during the fourth process, the deficient pattern portion of the resist pattern is detected automatically by the visual inspection system, whereby all surface defects of the surface electrode may be detected.
(3) Further, in the method of manufacturing the semiconductor device according to the present disclosure, in (2) above, a width of the resist left in the resist pattern may be narrower than the width of the surface defect, and the width of the through-hole of the resist of the resist pattern may be narrower than the width of the surface defect.

According to the disclosure above, during the fourth process, two types of deficient pattern portions (deficient pattern portion due to exposure focus error, deficient pattern portion due to lack of resist) of the resist pattern may be accurately detected by the visual inspection system.
(4) Further, in the method of manufacturing the semiconductor device according to the present disclosure, in (2) above, a width of the resist left in the resist pattern may be not more than ¼ of the width of the surface defect, and the width of the through-hole of the resist of the resist pattern may be not more than ¼ of the width of the surface defect.

According to the disclosure above, during the fourth process, two types of deficient pattern portions of the resist pattern may both be accurately detected by the visual inspection system.
(5) Further, in the method of manufacturing the semiconductor device according to the present disclosure, in any one of (1) to (4) above, in the third process, the resist pattern may be formed having regularity.

According to the disclosure above, during the fourth process, deficient pattern portions of the resist pattern are easily detected by the visual inspection system.
(6) Further, in the method of manufacturing the semiconductor device according to the present disclosure, in any one of (1) to (5) above, in the third process, the resist pattern may be formed so that an area of resist left is equal to an area of the through-holes.

According to the disclosure above, during the fourth process, two types of deficient pattern portions of the resist pattern may both be accurately detected by the visual inspection system.
(7) Further, in the method of manufacturing the semiconductor device according to the present disclosure, in any one of (1) to (6) above, the surface defect includes a convex defect in which a portion of a surface of the surface electrode is raised, or a concave defect in which a portion of the surface of the surface electrode is recessed, or both the convex defect and the concave defect. In the third process, the surface of a first portion of the resist film on a normal portion of the surface electrode free of the surface defect is set as a focal point of the exposing, and the exposing the resist film may be performed using light having a short wavelength so that the focal point of the exposing is not aligned with a surface of a second portion of the resist film on the surface defect to thereby form the resist pattern.

According to the disclosure above, a convex defect and a concave defect of the surface of the surface electrode may both be detected.
(8) Further, in the method of manufacturing the semiconductor device according to the present disclosure, in (7) above, the first process may include depositing the surface electrode by sputtering, and patterning the surface electrode by photolithography and etching. In this instance, the convex defect occurs due to foreign matter being incorporated in the surface electrode during the depositing, and the concave defect occurs due to the surface electrode being selectively removed at a deficient resist portion of a resist mask (31) used during the etching.

According to the disclosure above, during the first process, a convex defect and a concave defect occurring at the surface of the surface electrode may be detected.
(9) Further, in the method of manufacturing the semiconductor device according to the present disclosure, in any one of (1) to (8) above, the third process may include forming the resist pattern for each of a plurality of chip regions provided with regularity on the semiconductor wafer. The fourth process may include photographing the surface of the semiconductor wafer using the photographing mechanism and comparing images of two adjacent ones of the plurality of chip regions of the semiconductor wafer.

According to the disclosure above, a deficient resist portion of the resist pattern may be detected without preparing comparison images in advance.

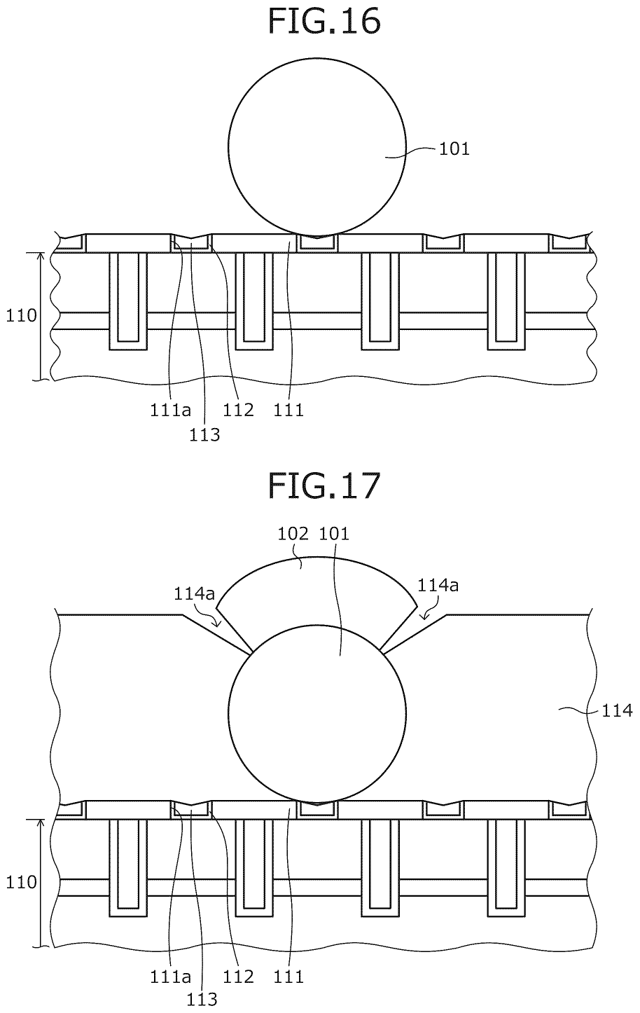

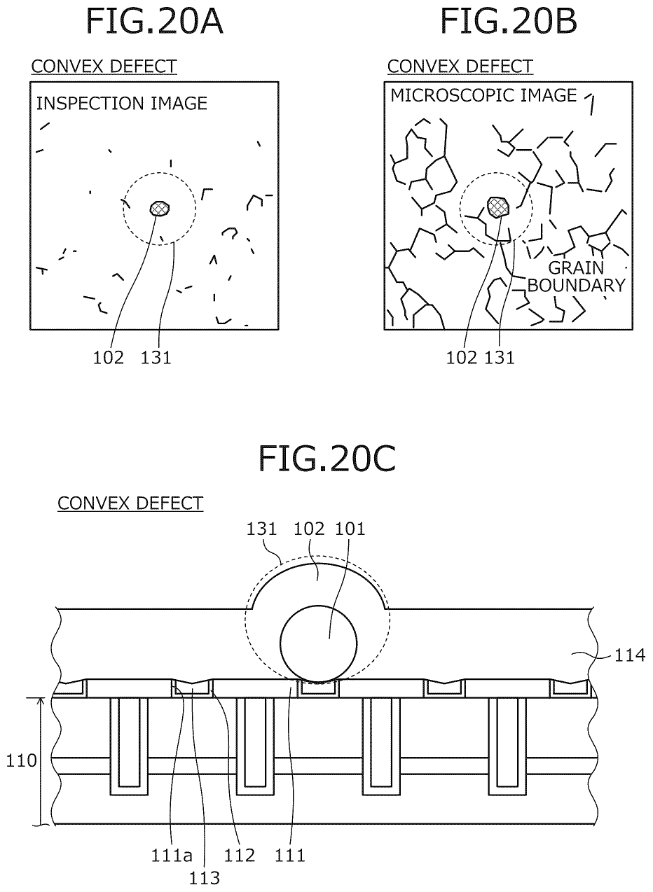

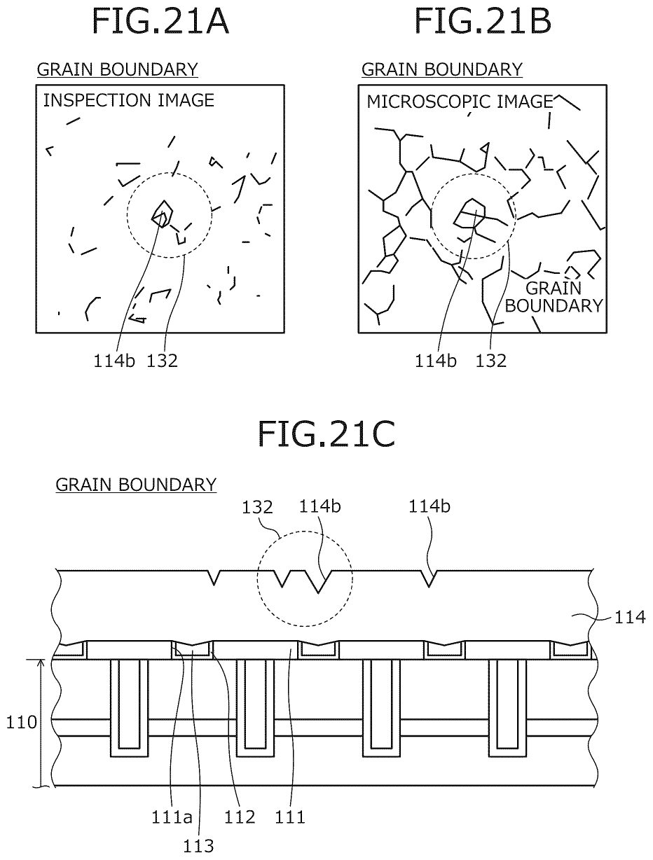

Findings underlying the present disclosure are discussed. First, a method of manufacturing a semiconductor device of a reference example is described. FIGS. 16, 17, 18, and 19 are cross-sectional views schematically depicting states of the semiconductor device of the reference example during manufacture. FIGS. 20A, 20B, 20C, 21A, 21B, and 21C are diagrams schematically depicting states of a convex defect of a surface electrode and grain boundaries at the time of inspection. With respect to inspection sites 131, 132, FIGS. 20A and 21A depict inspection images (plan views) by a visual inspection system; FIGS. 20B and 21B depict microscopic images (plan views) by visual inspection by a site-operator; and FIGS. 20C and 21C are corresponding cross-sectional views. For example, contact plugs 113 are embedded in contact holes 111a of an interlayer insulating film 111 via a barrier metal 112 and after a metal film constituting the contact plugs 113 is etched back, foreign matter 101 adheres to a front surface of a semiconductor wafer 110 (FIG. 16).

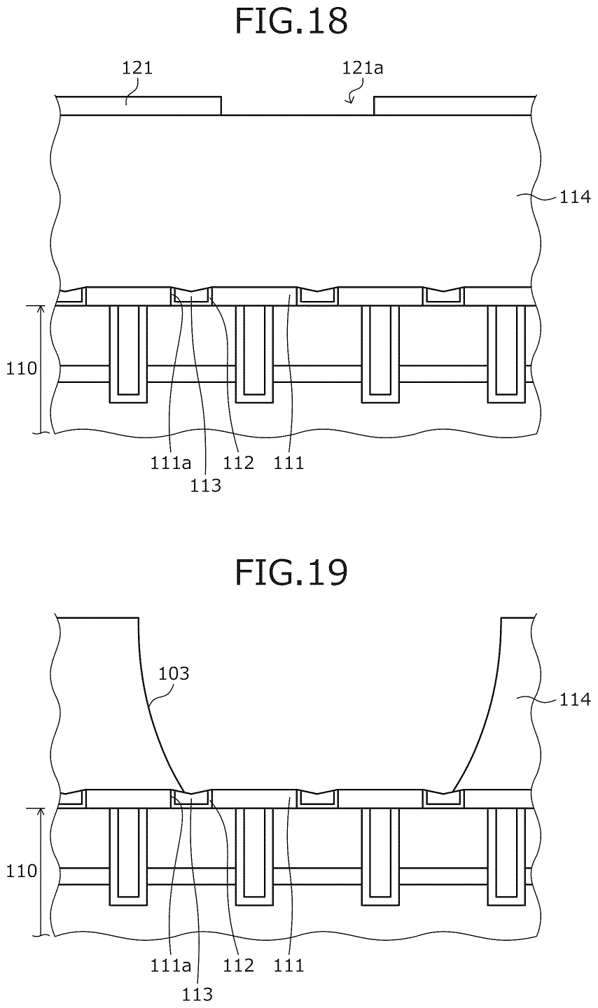

When a surface electrode 114 is deposited by sputtering while the foreign matter 101 is adhered to the front surface of the semiconductor wafer 110, the foreign matter 101 is incorporated into the surface electrode 114. Due to a relatively large size of the foreign matter 101, the surface of the surface electrode 114 is raised, whereby a convex defect 102 occurs at the surface of the surface electrode 114 (FIG. 17). When coverage of the surface electrode 114 degrades due to the foreign matter 101, cracking (metal deficiency) 114a near the convex defect 102 of the surface of the surface electrode 114 occurs. Further, when the resist film used as a mask during patterning of the surface electrode 114 thereafter has interruptions (breaks) due to the convex defect 102, the convex defect 102 exposed at the deficient resist portion is etched, whereby a concave defect (metal deficiency) 103 occurs penetrating through the surface electrode 114 in a depth direction (FIG. 19).

In a deficient resist portion 121a of a resist film 121 used as a mask during patterning of the surface electrode 114, even when the deficient resist portion 121a is caused by a factor other than the convex defect 102 (FIG. 18), the surface electrode 114 is selectively etched, whereby the concave defect 103 occurs (FIG. 19). The convex defect 102 is completely covered by the resist film and remains in this state (FIG. 20C). When a metal deficiency (the cracking 114a, the concave defect 103) occurs in the surface electrode 114, plating solution permeates the layer below during a plating treatment to the surface of the surface electrode 114, whereby non-conforming electrical characteristics (assembly defects) occur. Thus, after patterning of the surface electrode 114 but before annealing of the surface electrode 114, automated visual inspection to screen for defects occurring after deposition of the surface electrode 114 is performed using a visual inspection system.

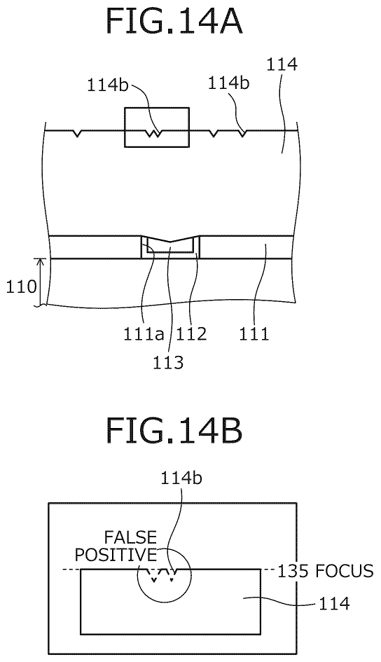

A particle size of grain boundaries (grains) 114b occurring during deposition of the surface electrode 114 is extremely small compared to widths and heights of the convex defect 102 and the concave defect 103 (in FIGS. 14A, 14B and 21, for the sake of description, the grain boundaries 114b are enlarged). However, in an area where the grain boundaries 114b are dense and adjacent to one another, in the visual inspection system, an inspection image of the grain boundaries 114b (FIG. 21A) resembles an inspection image of the convex defect 102 (FIG. 20A) and thus, the grain boundaries 114b may be falsely detected as a pseudo-defect (false-positive) of the convex defect 102 (hatched areas in FIGS. 20A and 20B). Since false-positive detection such as this may occur with the visual inspection system, after the inspection by the visual inspection system, defects detected by the visual inspection system have to be re-evaluated by a visual inspection (manual visual inspection) performed by a site-operator. As a result, throughput diminishes.

A pseudo-defect is a defect that is re-evaluated by a manual visual inspection and determined to be conforming by a site-operator (FIGS. 20B and 21B are microscopic images inspected by a site-operator). Thus, as the number of false-positives by the visual inspection system for similar defects increases, the labor for the manual visual inspection performed for re-evaluation by the site-operator increases. While the number of false-positives for the grain boundaries 114b by the visual inspection system may be reduced by changing the deposition conditions for the surface electrode 114 to reduce the grain boundaries 114b or by using a light source with high brightness to increase contrast of the inspection image of the visual inspection system, the speed of deposition of the surface electrode 114 decreases, whereby production capacity of the semiconductor chip decreases and detection sensitivity of the visual inspection system decreases due to halation. The present embodiment enhances visual inspection sensitivity and improves throughput.

Embodiments of a method of manufacturing a semiconductor device according to the present disclosure are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and are not repeatedly described.

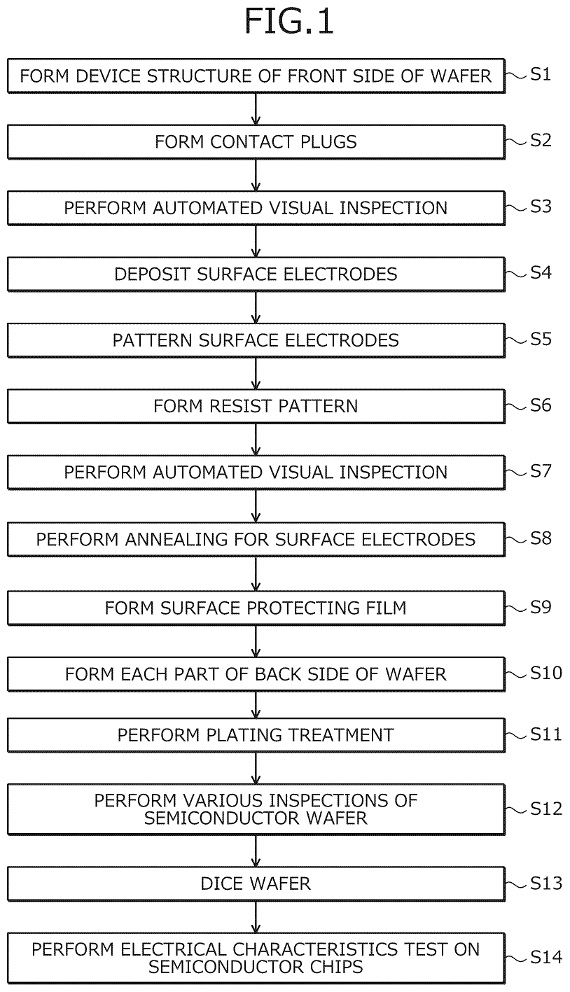

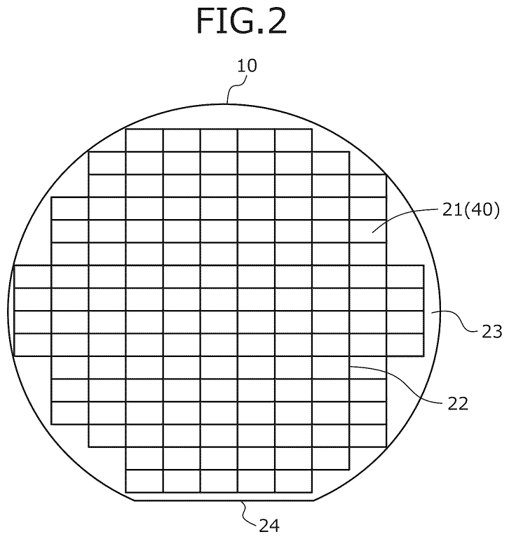

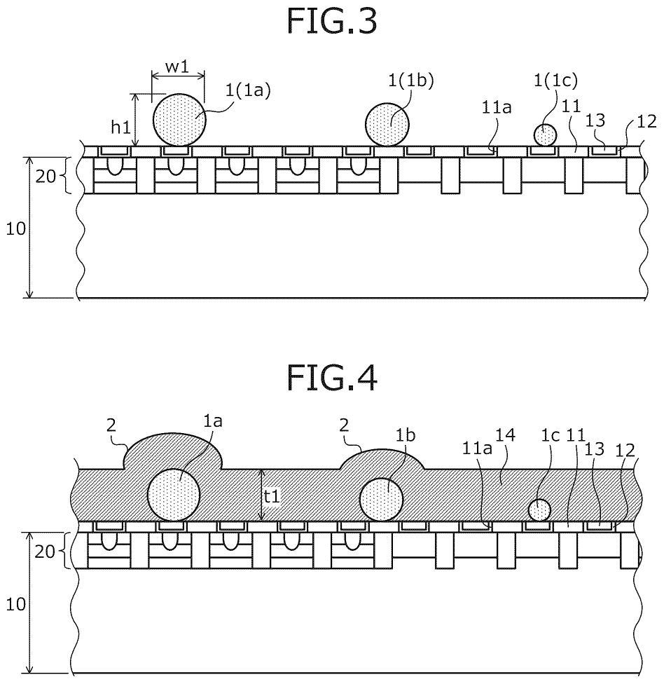

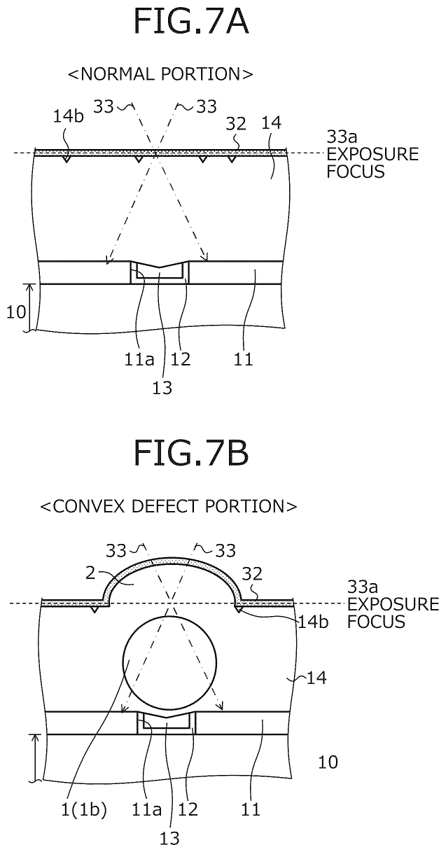

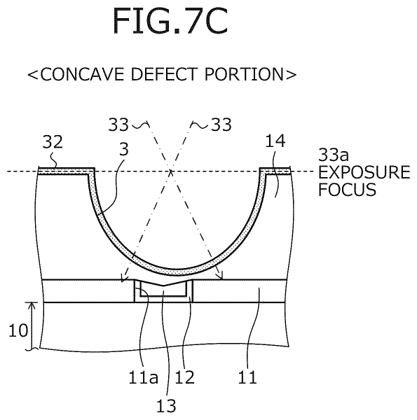

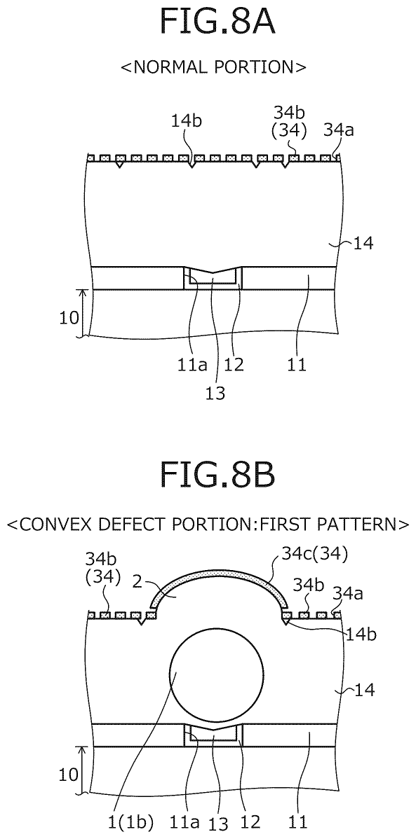

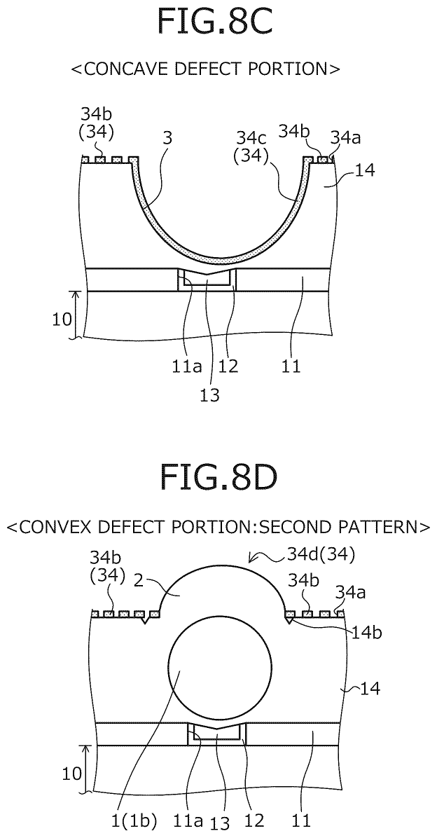

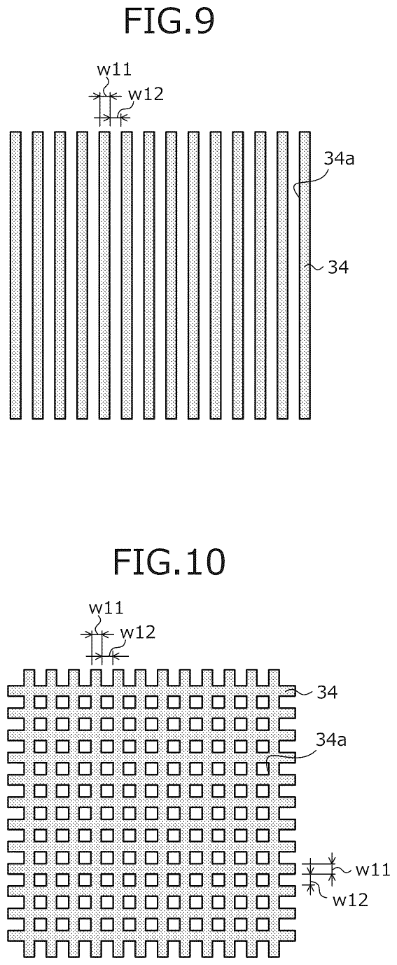

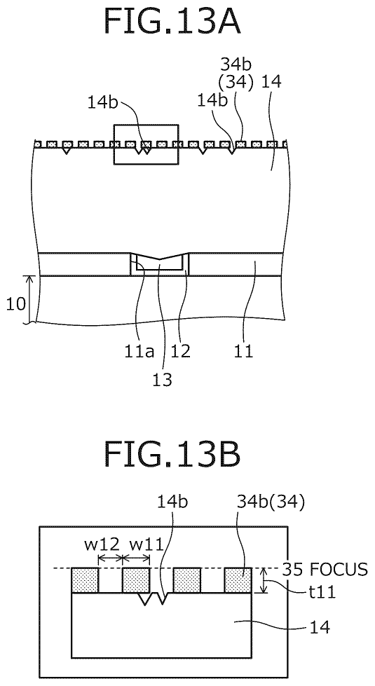

A method of manufacturing a semiconductor device that solves the problems described above is described. FIG. 1 is a flowchart showing an outline of the method of manufacturing the semiconductor device according to the embodiment. FIG. 2 is a plan view depicting a state when a semiconductor wafer is viewed from front side thereof. FIGS. 3, 4, 5, 6, 7A, 7B, 7C, 8A, 8B, 8C, 8D, 13A, and 13B are cross-sectional view depicting states of the semiconductor device according to the embodiment during manufacture. FIGS. 9, 10, 11, and 12 are plan views depicting examples of a resist pattern at step S6 in FIG. 1. FIGS. 3 to 6 depict a mechanism of defect generation during processes at steps S4, S5 in FIG. 1. FIGS. 7A, 7B, 7C, 8A, 8B, 8C, and 8D depict states during a process at step S6 in FIG. 1 and FIGS. 13A, and 13B, depict states during a process at step S7 in FIG. 1. FIGS. 13A, and 13B, schematically depict grain boundaries 14b larger than in actuality relative to a resist pattern 34. FIGS. 14A and 14B are cross-sectional views depicting states of the semiconductor device of the reference example during manufacture.

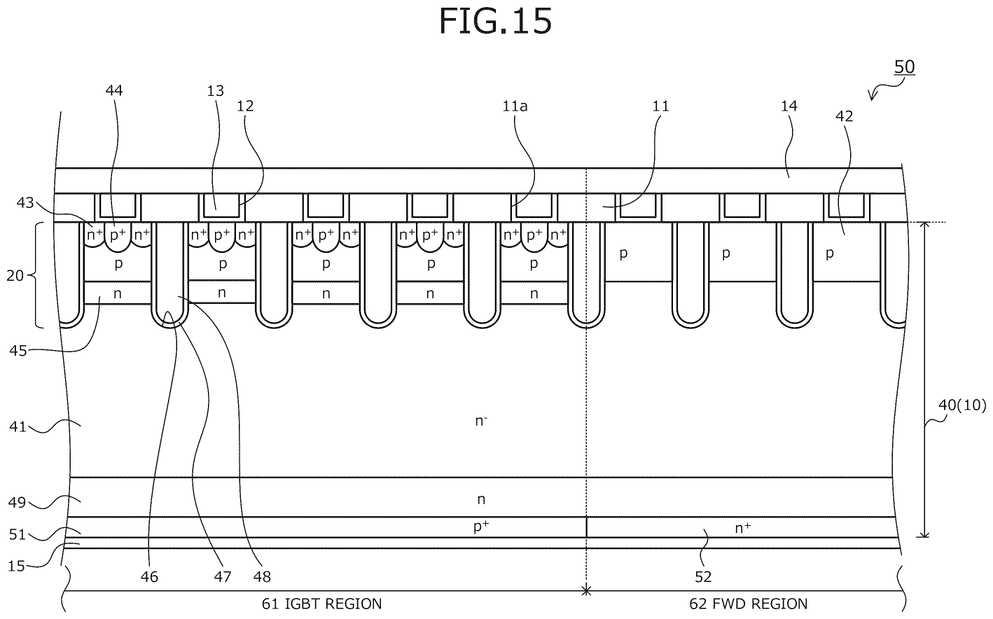

First, as depicted in FIGS. 2 and 3, in a semiconductor wafer 10, at a front surface thereof, a predetermined device structure 20 is formed in each of multiple chip regions 21 (step S1). Next, in an entire area of the front surface of the semiconductor wafer 10, an interlayer insulating film 11 is formed and contact holes 11a penetrating through the interlayer insulating film 11 in the depth direction are formed. In each of the contact holes 11a, a contact (electrical contact) between the device structure 20 and a later-described surface electrode 14 is formed. While the device structure 20 is described hereinafter (refer to FIG. 15), for example, in an instance in which the device structure 20 is a structure in which a cell pitch is decreased to reduce device size and on-resistance, a width of each of the contact holes 11a is decreased and thus, embeddability of the contact holes 11a by later-described contact plugs 13 is enhanced.

A size of the semiconductor wafer 10 may be suitably set and, for example, a diameter thereof may be 8 inches. A material of the semiconductor wafer 10 may be silicon (Si) or silicon carbide (SiC). The chip regions 21 are regions that are cut from the semiconductor wafer 10, along dicing lines 22, to form individual semiconductor chips 40. The dicing lines 22 extend in a grid-like pattern so as to border peripheries of the chip regions 21, which are disposed adjacent to one another in a matrix-like pattern in a plan view. Between an end (wafer end) of the semiconductor wafer 10 and an outermost one of the dicing lines 22 closest to the wafer end, may be a non-operating region 23 that is not used as the semiconductor chips 40. The semiconductor wafer 10 may have an orientation flat 24 or a notch (not depicted) indicating crystal orientation.

Next, by a sputtering method, a barrier metal 12 is formed along the surface of the interlayer insulating film 11 and inner walls of the contact holes 11a. The barrier metal 12, for example, is formed by a titanium (Ti) film and a titanium nitride (TIN) film that are sequentially stacked in the order stated. Next, by a chemical vapor deposition (CVD) method, for example, a conductive film such as a tungsten (W) film is deposited (formed) on the barrier metal 12 so as to be embedded in the contact holes 11a. Next, the tungsten film is etched, leaving only portions thereof constituting the contact plugs 13 in the contact holes 11a (step S2).

Next, visual inspection of the semiconductor wafer 10 is performed using a general visual inspection system (not depicted) (step S3). In the inspection at step S3, embedding of the contact plugs 13 is confirmed. As a method of confirming the embedding of the contact plugs 13, for example, flatness of the front surface of the semiconductor wafer 10 (the surface of the interlayer insulating film 11 and the surfaces of the contact plugs 13) may be confirmed, absence of voids in the contact plugs 13 may be confirmed, or it may be confirmed that voids occurring in the contact plugs 13 do not adversely affect electrical characteristics. Position information of the chip regions 21 determined to be non-conforming by the inspection at step S3 is stored to a predetermined recording medium.

Next, as depicted in FIG. 4, the surface electrode 14 is deposited (formed) on the interlayer insulating film 11 and the contact plugs 13 by a sputtering method (step S4: the first process (deposition process)). The surface electrode 14, for example, is an Al alloy film such as an aluminum-silicon (Al—Si) film or an aluminum-silicon-copper (Al—Si—Cu) film. A thickness t1 of the surface electrode 14, for example, is about 5 μm. For example, foreign matter 1 adhered to the front surface of the semiconductor wafer 10 (respective surfaces of the interlayer insulating film 11 and the contact plugs 13) by etching or the like at step S2 (refer to FIG. 3) becomes incorporated in the surface electrode 14 during the process at step S4. Here, an instance in which the foreign matter 1 (1a, 1b, 1c) each having a different height are adhered on the semiconductor wafer 10.

Due to the foreign matter 1a, 1b, the surface of the surface electrode 14 is raised, whereby convex defects 2 (convex surface defects) occur at the surface of the surface electrode 14. The foreign matter 1a has a relatively large size with a height 1 at least equal to the thickness t1 of the surface electrode 14 and, for example, a width w1 that is about 7 μm or more. The foreign matter 1a, which has a relatively large size, and the foreign matter 1b, which has a height that is less than the thickness t1 of the surface electrode 14 but relatively close to the thickness t1 of the surface electrode 14 cause the convex defects 2. Due to the height 1 of the foreign matter 1a, coverage of the surface electrode 14 is degraded and cracking occurs near the convex defects 2 of the surface of the surface electrode 14 (corresponds to the cracking 114a in FIG. 17). Depending on the shape of the foreign matter 1c, which has a relatively small size, the foreign matter 1c may be buried in the surface electrode 14, whereby the convex defects 2 do not occur.

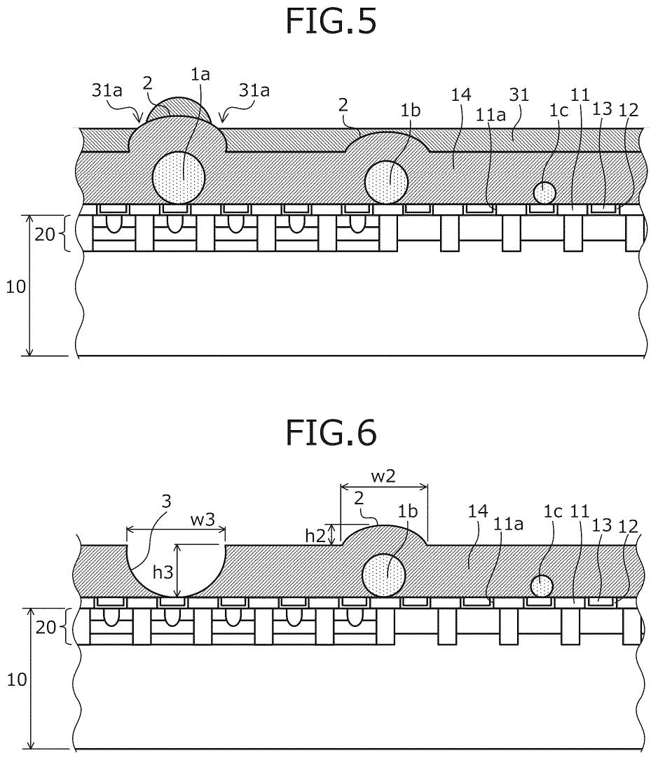

Next, the surface electrode 14 is patterned by photolithography and etching (step S5: the first process (etching process)). At step S5, as depicted in FIG. 5, a resist film (resist mask) 31 covering active regions of the chip regions 21 is formed on the surface electrode 14. In openings (not depicted) of the resist film 31, edge termination regions and the dicing lines 22 are exposed. Further, etching is performed using the resist film 31 as a mask, thereby selectively removing the surface electrode 14 and leaving portions thereof in a predetermined pattern in each of the active regions of the chip regions 21. Each of the active regions is a region through which a main current flows during an on-state. Each of the edge termination regions is a region between a corresponding one of the active regions and a side surface of a corresponding one of the semiconductor chips 40 (refer to FIG. 15), and each surrounds a periphery of said active region in a plan view. Subsequently, as depicted in FIG. 6, the resist film 31 is removed.

During the process at step S5, when the resist film 31 has interruptions (breaks) due to the convex defects 2, the convex defects 2 (the foreign matter 1a and a portion of the surface electrode 14 in a vicinity thereof) exposed at a deficient resist portion 31a of the resist film 31 are etched, whereby a concave defect (metal deficiency) 3, which is a recessed (concave) portion of the surface of the surface electrode 14, occurs (FIG. 6). Also, at a deficient resist portion (corresponds to the deficient resist portion 121a in FIG. 18) occurring in the resist film 31 due to a factor other than the convex defects 2 (for example, variation of the thickness of the resist film 31), the surface electrode 14 is selectively etched, whereby the concave defect 3 (concave surface defect) occurs. The concave defect 3, for example, penetrates through the surface electrode 14 in the depth direction. The convex defects 2 (the convex defect 2 due to the foreign matter 1b) that are completely covered by the resist film 31 remain in this state at the surface of the surface electrode 14 even after the process at step S5 (FIG. 6).

It is presumed that the number of the convex defects 2 that remain after the process at step S5 and the number of the concave defect 3 that occur due to the process at step S5 are nearly equal. The convex defects 2 that remain after the process at step S5 are raised, having a height h2 in a range of, for example, about 3 μm to 5 μm from a surface of a normal portion (a substantially flat portion free of the convex defects 2 and the concave defect 3) of the surface electrode 14. A width w2 of the convex defects 2 that remain after the process at step S5 is, for example, about 11 μm or more. A depth h3 of the concave defect 3 is about equal to the thickness t1 of the surface electrode 14. A width w3 of the concave defect 3, for example, is about 21 μm or more. Height differences due to unevenness of the surface of the surface electrode 14, resulting from manufacturing variation by sputtering is in a range of about +0.05 μm to 0.5 μm, which is small as compared to the height h2 of the convex defects 2 and the depth h3 of the concave defect 3. The particle size of the grain boundaries 14b of the surface electrode 14 is extremely small as compared to the width w2 and the height h2 of the convex defects 2 of the surface electrode 14 and the width w3 and the depth h3 of the concave defect 3 (in FIGS. 7A, 7B, 7C, 8A, 8B, 8C, 8D, 13A, 13B, and 13C, for the sake of description, the grain boundaries 14b are depicted larger than in actuality).

Next, as depicted in FIGS. 7A, 7B, 7C, a resist film 32 (hatched portion) is formed on the surface of the surface electrode 14 (the second process). The resist film 32 is formed along the surface of a normal portion of the surface electrode 14 (FIG. 7A), the surface of the convex defects 2 (FIG. 7B), and the inner wall of the concave defect 3 (FIG. 7C). Next, a predetermined mask pattern is transferred (exposed onto) the resist film 32, using general exposure equipment. At this time, an exposure focus (focus of light 33 of a light source of the exposure equipment) 33a is aligned with the surface (focal point (imaging plane)) of a portion of the resist film 32 on the normal portion of the surface electrode 14. In FIGS. 7A, 7B, and 7C, the light 33 of the light source of the exposure equipment is indicated by oblique dot-dash chained arrows while position of an exposure focus 33a is indicated by a horizontal dashed line passing through a point of intersection of rays of the light 33. Further, as depicted in FIGS. 8A, 8B, 8C, and 8D, exposed portions of the resist film 32 are dissolved by a chemical solution and removed (developed), thereby forming the resist pattern 34 (hatched portion) on the surface electrode 14 of each of the chip regions 21 of the semiconductor wafer 10 (the third process) (step S6).

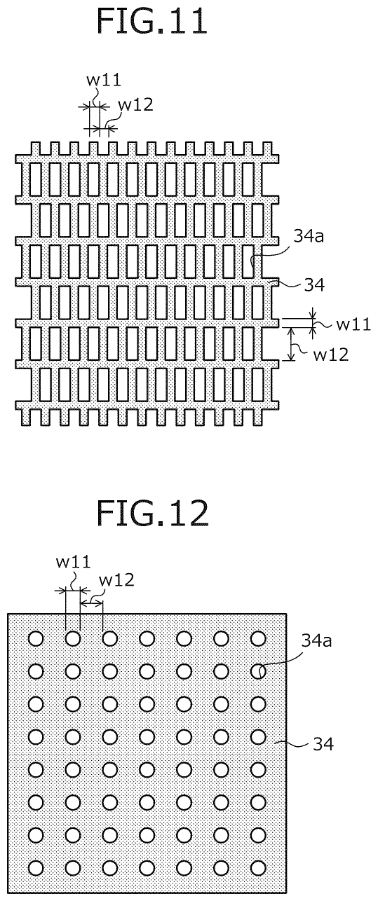

To expose the resist film 32 at step S6, for example, a light source is used that emits the light 33, which has a short wavelength (low depth of focus), such as i-line (light with a wavelength of 365 nm) or KrF-line (excimer laser light of krypton fluoride having a wavelength of 248 nm). As a result, widths w12, w11 of both removed portions and left portions (exposed portions and unexposed portions) of the resist may form the fine resist pattern 34 that is narrower than the narrower of the width w2 of the convex defects 2 and the width w3 of the concave defect 3 of the surface electrode 14. While the resist pattern 34 may be suitably set, having regularity is favorable. In particular, the resist pattern 34, for example, may be a stripped pattern (FIG. 9) or a grid-like pattern (FIG. 10) in which the widths w12, w11 of removed portions and left portions of the resist are substantially equal, or may be rectangular shapes arranged in a matrix-like pattern (FIG. 11), or may be a reticulated pattern (uneven grid: FIG. 11) in which peripheries of circular shaped (pin-hole shaped: FIG. 12) through-holes 34a are surrounded.

The resist pattern 34 is a pattern having regularity, whereby in a process at later-described step S7, deficient pattern portions 34c, 34d of the resist pattern 34 are easily detected and thus, inspection throughput is enhanced. The exposure focus 33a is aligned with the surface of the portion of the resist film 32 on the normal portion of the surface electrode 14, whereby the resist film 32 is exposed normally on the normal portion of the surface electrode 14. Thus, the portion of the resist pattern 34 on the normal portion of the surface electrode 14 has a normal pattern portion 34b in which removed portions and left portions of the resist having the widths w12, w11, respectively, repeatedly alternate with one another, which is a same pattern as the mask pattern transferred to the resist film 32 (FIG. 8A). On the other hand, the surface of portions of the resist film 32 on the convex defects 2 and on the concave defect 3 of the surface electrode 14 is positioned apart from the depth of focus of the light 33 of the light source of the exposure equipment. Thus, the portions of the resist pattern 34 on the convex defects 2 and the portion on the concave defect 3 have the deficient pattern portion 34c in which resist remains and is left having a width wider than the width w11 of the normal pattern portion 34b (FIGS. 8A, 8C).

In other words, in the exposure of the resist film 32, a light source that emits the light 33 having a shallow depth of focus (for example, i-line depth of focus is about 500 nm) is used, whereby the exposure focus 33a, for the most part, does not align with the portions of the surface of the resist film 32 on the convex defects 2 and on the concave defect 3 of the surface electrode 14 (FIGS. 7B and 7C) and the resist film 32 is not exposed. A portion of the resist film 32 not exposed becomes the deficient pattern portion 34c. Thus, the light 33 of the light source of the exposure equipment used in exposing the resist film 32 suffices to be light for which ½ of the depth of focus thereof is shallower than the height h2 of the convex defects 2 and ½ of the depth of focus thereof is shallower than the depth h3 of the concave defect 3. As described, an error of the exposure focus 33a is intentionally caused during exposure of the resist film 32, whereby the portions of the resist pattern 34 on the convex defects 2 and on the concave defect 3 may be caused to be the deficient pattern portion 34c. In the process at later-described step S7, the deficient pattern portion 34c of the resist pattern 34 is detected, whereby the convex defects 2 and the concave defect 3 of the surface electrode 14 may all be automatically detected by the visual inspection system.

A unit pattern of the removed portions and the left portions of the resist of the resist pattern 34 is a pattern of one set of a removed portion and a left portion of the resist adjacent to one another) and preferably, a combined width of at least two unit patterns (=2×(w11+w12)) may be not more than a width (width that is narrower of the width w2 of the convex defect 2 and the width w3 of the concave defect 3) of the surface defects. In other words, preferably, a combined width of the width w11 of the resist left in the normal pattern portion 34b of the resist pattern 34 and the width w12 of the through-holes of the resist (=w11+w12) may be not more than ½ of the width of the surface defects. As a result, in the process at later-describe step S7, the normal pattern portion 34b and the deficient pattern portion 34c of the resist pattern 34 may be easily distinguished. As for portions of the resist pattern 34 on the convex defects 2 having the height h2 that is relatively high, rather than forming the deficient pattern portion 34c, the deficient pattern portion 34d is formed in which the resist film 32 is not formed on the convex defects 2 (is free of resist) (FIG. 8D). The width of the deficient pattern portion 34d is wider than the width w12 of the through-holes of the resist in the normal pattern portion 34b.

Preferably, the combined width of the resist left in the normal pattern portion 34b of the resist pattern 34 and the width w12 of the through-holes of the resist, for example, may be about 5.5 μm or less. A numerical range (11 μm/2=5.5 μm) of these combined widths (=w11+w12) is calculated based on an assumption that, as described above, the combined width of at least two unit patterns of a removed portion and a left portion of the resist of the resist pattern 34 is not more than the width (here, the width w2 of the convex defects 2) of detected symmetrical defects. The resist left in the normal pattern portion 34b of the resist pattern 34 and the width w12 of the through-holes of the resist, for example, are suitably adjusted to be within a range not more than 2.75 mm, and an area of the resist left and an area of the resist through-holes are equal to each other, whereby even in an instance in which the width w11 of the resist left in the normal pattern portion 34b of the resist pattern 34 and the width w12 of the through-holes of the resist are not equal to each other, in the process at later-describe step S7, the two types of the deficient pattern portions 34c, 34d of the resist pattern 34 may both be detected with accuracy.

Preferably, a thickness (thickness of the resist film 32) t11 of the resist pattern 34, for example, may be in a range of 1 μm to 2.75 μm. A reason that the thickness t11 of the resist pattern 34 is not less than the lower limit above is that, when the thickness t11 of the resist pattern 34 is too thin, in an inspection at later-described step S7, a focus 35 of an inspection unit or irradiated light of the visual inspection system may be impossible to align with the surface of the resist pattern 34. A reason that the thickness t11 of the resist pattern 34 is not more than the upper limit above is that an aspect ratio of the removed portions to the left portions of the resist (=the thickness t11 of the resist pattern 34/the width w11 of the resist left to remain, or =the thickness t11 of the resist pattern 34/the width w12 of the through-holes of the resist) is reduced (for example, 1 or more) and formation of the fine resist pattern 34 is facilitated.

Next, a visual inspection of the semiconductor wafer 10 is performed using a general visual inspection system (not depicted) (step S7: the fourth process). In the inspection at step S7, for all the chip regions 21 of the semiconductor wafer 10, detection of the convex defects 2 and the concave defects 3 of the surface electrode 14 is performed by the visual inspection system. For example, first, the deficient pattern portions 34c, 34d of the resist pattern 34 are detected. For example, one method of detection includes irradiating light on the front surface of the semiconductor wafer 10 from a predetermined light source equipped in the visual inspection system and detecting the deficient pattern portions 34c, 34d of the resist pattern 34 based on an intensity ratio of the reflected scattered light, using a program prepared in the visual inspection system.

As another example, there is a method that includes photographing the chip regions 21 on the semiconductor wafer 10 by the inspection unit and comparing the resist patterns of adjacent ones of the chip regions 21 using a program prepared in the visual inspection system and thereby, detecting the deficient pattern portions 34c, 34d of the resist pattern 34. The image of the resist pattern 34 photographed by the inspection unit may be compared to a comparison image registered in the visual inspection system in advance. The inspection unit is a device having a photographing mechanism such as a camera and is incorporated in the visual inspection system. The inspection unit may have a microscope, a light, a monitor, various types of sensors, etc. in addition to the photographing mechanism.

As described, the deficient pattern portions 34c, 34d of the resist pattern 34 occur on the convex defects 2 and on the concave defects 3 of the surface electrode 14 and thus, detection positions of the deficient pattern portions 34c, 34d by the visual inspection system may be regarded as detection positions of the convex defects 2 and the concave defect 3. At this time, as depicted in FIGS. 13A, 13B, and 13C, the focus 35 of the inspection unit or the irradiated light of the visual inspection system is aligned with the (focal point (imaging plane)) of the resist pattern 34 and thus, the focus 35 is not aligned with the grain boundaries 14b of the surface electrode 14 and therefore, even in an area where the grain boundaries 14b are dense and adjacent to one another, the grain boundaries 14b are not falsely detected.

In the method of manufacturing the semiconductor device of the reference example described above, as depicted in FIGS. 14A and 14B, a focus 135 of an inspection unit of irradiated light of a visual inspection system is aligned with the surface of the surface electrode 114 and the grain boundaries 114b of the surface electrode 114 are falsely detected as similar defects of the convex defect 102 (refer to FIGS. 20A, 20B, 20C, 21A, 21B, and 21C). Thus, the grain boundaries 114b falsely detected by the visual inspection system have to be re-evaluated and judged to be conforming by manual visual inspection performed by a site-operator. On the other hand, in the embodiment, in the inspection at step S7, the grain boundaries 14b are not falsely detected and thus, re-evaluation by manual visual inspection performed by a site-operator is unnecessary in the inspection at step S7. Thus, in the overall flow of manufacturing, labor for re-evaluation by manual visual inspection performed by a site-operator may be reduced. The position information of the chip regions 21 of the convex defects 2 or the concave defects 3 or both detected by the inspection at step S7 is stored to a predetermined recording medium.

Next, annealing (heat treatment) for sintering the surface electrode 14 is performed (step S8). In the process at step S8, an ohmic contact between the barrier metal 12 and the semiconductor wafer 10 may be formed. Next, on the front surface of the semiconductor wafer 10 (the surface of the surface electrode 14), for example, a surface protecting film (passivation film: not depicted) containing a polyimide is formed (step S9). Next, openings are formed in the surface protecting film by photolithography and etching, thereby exposing the surface electrode 14 of each of the chip regions 21 in the openings of the surface protecting film. A portion of the surface electrode 14 exposed in an opened portion of the surface protecting film constitutes an electrode pad. Next, by a general method, regions of a back side of the semiconductor wafer 10 are formed (step S10).

In a process at step S10, for example, the semiconductor wafer 10 is ground from the back side thereof to a product thickness for use as a semiconductor device 50 (refer to FIG. 15). Next, in the semiconductor wafer 10, at the back surface thereof after grinding, predetermined diffused regions (an n⁺-type FS layer 49, a p⁺-type collector region 51, and an n⁺-type cathode region 52 in FIG. 15) are formed by ion implantation. From the front surface or the back surface of the semiconductor wafer 10, for example, helium (He) may be irradiated to thereby introduce a lifetime killer in a predetermined region in the semiconductor wafer 10. Next, a surface electrode (a back electrode 15 in FIG. 15) of the back surface of the semiconductor wafer 10 is formed by a sputtering method. Next, a plating film (not depicted) is formed on the surface of the surface electrode 14 by a plating treatment (step S11).

Next, various types of inspections of the semiconductor wafer 10 are performed (step S12), whereby a wafer process is completed. The inspections at step S12 are electrical characteristics tests in which a probe needle is brought into contact with each electrode pad of all the chip regions 21 and electrical signals are input and output, whereby basic functions and characteristics are inspected, and for each of the chip regions 21 of the semiconductor wafer 10, it is determined whether the chip region 21 conforms or does not conform. The electrical characteristics tests may include, for example, evaluating electrical characteristics of the semiconductor device 50, such as on-voltage, threshold voltage, and leakage current between terminals, to thereby screen the chip regions 21 that do not conform with specifications. The position information of the chip regions 21 determined to be non-conforming by the inspections at step S12 are stored to a predetermined recording medium.

In addition to the inspections at steps S3, S7, and S12 described above, at a predetermined timing, inspections of the semiconductor wafer 10 (for example, inspections of mutual positional relationships, dimensions, patterns, etc. of regions) may be performed by a visual inspection by the visual inspection system or a site-operator. In these inspections as well, the position information of the chip regions 21 determined to be non-conforming is stored to a predetermined recording medium. In an inspection at a subsequent step, the position information of the chip regions 21 determined to be non-conforming and stored in the predetermined recording medium is referred to, and inspection may be performed with respect to only the chip regions 21 that have not been determined to be non-conforming. In other words, each time the semiconductor wafer 10 is inspected, the chip regions 21 that have been determined to be non-conforming are excluded from being inspected, the manufacturing flow progresses, whereby inspection throughput of the semiconductor wafer 10 may be enhanced.

Next, the semiconductor wafer 10 is cut (diced) along the dicing lines 22, whereby the chip regions 21 are cut into the individual semiconductor chips 40 (refer to FIG. 15) (step S13). Next, the individual semiconductor chips 40 constituted by the chip regions 21 that have not been determined to be non-conforming by the inspections at steps S3, S7, and/or S12 described above are picked up and the electrical characteristics tests are performed therefor (step S14), the semiconductor chips 40 that are determined as being conforming are assumed to be a product (the semiconductor device 50). A process at step S14, for example, includes a reliability test such as a high-temperature/high-humidity bias (temperature/humidity bias (THB)) test, a high-temperature reverse bias (HTRB) test.

The semiconductor chips 40 determined to be conforming are packaged in semiconductor modules at a subsequent assembly process. Further, a predetermined reliability test is performed while a temperature load and a voltage load are placed on the semiconductor module (burn-in) and non-conforming modules are removed. This reliability test includes screening semiconductor modules that are non-conforming due to changes in gate characteristics occurring with burn-in. For example, as described later, when the semiconductor chips 40 include a FWD region 62, in the reliability test of the semiconductor module, while non-conforming characteristics occurring in the FWD region 62 due to the convex defects 2 and the concave defects 3 of the surface electrode 14 are not detected, the convex defects 2 and the concave defects 3 of the surface electrode 14 are reliably detected by the process at step S7 described above and thus, non-conforming modules may be reduced.

The method of manufacturing the semiconductor device described in the present embodiment may be implemented by executing a prepared program on a computer such as a personal computer or a workstation, a database server, a web server, or the like. Information obtained during the manufacture of the semiconductor device described in the present embodiment is stored to a computer-readable recording medium such as a solid-state drive (SSD), a hard disk, a Blu-ray (registered trademark) disk (BD), a USB flash memory, and is used by being appropriately read out from the recording medium by a computer or a server.

An example of a structure of the semiconductor device manufactured by adopting the method of manufacturing the semiconductor device according to the embodiment above is described with reference to FIG. 15. FIG. 15 is a cross-sectional view depicting an example of the structure of the semiconductor device manufactured by adopting the method of manufacturing the semiconductor device according to the embodiment. FIG. 15 depicts the active region but does not depict the edge termination regions. The semiconductor device 50 depicted in FIG. 15 is a reverse conducting (RC)-IGBT in which a trench gate insulated gate bipolar transistor (IGBT) and a diode connected in parallel to the IGBT are integrated on a single one of the semiconductor chips (semiconductor substrates) 40. The semiconductor chips 40 are formed by dicing the chip regions 21 of the semiconductor wafer 10, in the process at step S13 described above.

In each of the semiconductor chips 40, at the front surface thereof, the device structure 20, the interlayer insulating film 11, the barrier metal 12, the contact plugs 13, and the surface electrode 14 described above are provided. In the active region, in each of the semiconductor chips 40, in a direction parallel to the front surface of the semiconductor chip 40, an IGBT region 61 constituting an operating region of the IGBT and the FWD region 62 constituting an operation region of a freewheeling diode (FWD) are provided adjacent to each other. A portion of each of the semiconductor chips 40 other than the device structure 20, the later-described n⁺-type FS layer 49, the p⁺-type collector region 51, and the n⁺-type cathode region 52 constitutes an n-type drift region 41. The device structure 20 is configured by a p-type base region 42, n⁺-type emitter regions 43, p⁺-type contact regions 44, trenches 46, gate insulating films 47, and gate electrodes 48.

The p-type base region 42, in the active region, is provided in an entire area between the front surface of the semiconductor chip 40 and the n-type drift region 41. The p-type base region 42 has a lower surface (surface facing the n⁺-type cathode region 52) in contact with the n-type drift region 41. The p-type base region 42 functions as a p-type anode region in the FWD region 62. The n⁺-type emitter regions 43 and the p⁺-type contact regions 44, in the IGBT region 61, are selectively provided between the front surface of the semiconductor chip 40 and the p-type base region 42; the FWD region 62 is free of the n⁺-type emitter regions 43 and the p⁺-type contact regions 44. The n⁺-type emitter regions 43 and the p⁺-type contact regions 44 each have a lower surface (surface facing the p⁺-type collector region 51) in contact with the p-type base region 42. The n⁺-type emitter regions 43 and the p⁺-type contact regions 44 are in contact with the barrier metal 12 at the front surface of the semiconductor chip 40.

The n⁺-type emitter regions 43 face the gate electrodes 48 at sidewalls of the trenches 46 with the gate insulating films 47 intervening therebetween. The p⁺-type contact regions 44 may be omitted. In an instance in which the p⁺-type contact regions 44 are omitted, instead of the p⁺-type contact regions 44, the p-type base region 42 reach the front surface of the semiconductor chip 40. In the IGBT region 61, an n-type carrier storage (CS) region 45 may be provided between and in contact with the p-type base region 42 and the n-type drift region 41. The trenches 46 penetrate through the p-type base region 42 from the front surface of the semiconductor chip 40 and terminate in the n-type drift region 41. The trenches 46 are provided in the IGBT region 61 and the FWD region 62. The gate insulating films 47 are provided along inner walls of the trenches 46. The gate electrodes 48 are provided on the gate insulating films 47 in the trenches 46.

The interlayer insulating film 11 is provided in an entire area of the front surface of the semiconductor chip 40. The contact holes 11a that penetrate through the interlayer insulating film 11 in the depth direction and reach the front surface of the semiconductor chips 40 are provided. In the contact holes 11a in the IGBT region 61, the n⁺-type emitter regions 43 and the p⁺-type contact regions 44 are exposed. In the contact holes 11a in the FWD region 62, the p-type base region 42 are exposed. The barrier metal 12 is provided along sidewalls (side surface of the interlayer insulating film 11) and bottoms (front surface of the semiconductor chip 40) of the contact holes 11a. The barrier metal 12, is in ohmic contact with the n⁺-type emitter regions 43 and the p⁺-type contact regions 44 in the contact holes 11a in the IGBT region 61 and is in contact with the p-type base region 42 in the contact holes 11a in the FWD region 62.

The contact plugs 13 are embedded on the barrier metal 12 in the contact holes 11a. The surface electrode 14 is provided on the interlayer insulating film 11 and the contact plugs 13. The surface electrode 14 is electrically connected to the p-type base region 42, the n⁺-type emitter regions 43, and the p⁺-type contact regions 44, via the contact plugs 13 and the barrier metal 12. The surface electrode 14 functions as an emitter electrode in the IGBT region 61 and functions as an anode electrode in the FWD region 62. In the n-type drift region 41 in the FWD region 62, at a position shallower from the front surface of the semiconductor chip 40 than is the n⁺-type FS layer 49, for example, a lifetime control region (not depicted) formed by introducing a lifetime killer by irradiating helium (He) may be provided.

The n⁺-type FS layer 49 is provided in an entire area between the back surface of the semiconductor chip 40 and the n-type drift region 41. The p⁺-type collector region 51 is provided between the back surface of the semiconductor chip 40 and the n⁺-type FS layer 49, in a region excluding the FWD region 62. The n⁺-type cathode region 52 is provided in the FWD region 62, between the back surface of the semiconductor chip 40 and the n⁺-type FS layer 49. The n⁺-type cathode region 52 is adjacent to the p⁺-type collector region 51 in a direction parallel to the back surface of the semiconductor chips 40. The back electrode 15 is provided on the back surface of the semiconductor chip 40 and is in contact with the p⁺-type collector region 51 and the n⁺-type cathode region 52. The back electrode 15 functions as a collector electrode in the IGBT region 61 and functions as a cathode electrode in the FWD region 62.

As described above, according to the embodiment, in multiple inspections (inspection by the visual inspection system, manual visual inspection by a site-operator) performed at predetermined timings to the semiconductor wafer, position information for a chip region that has been determined to be non-conforming is stored to a predetermined recording medium. Further, in a subsequent inspection, the position information of the chip regions determined to be non-conforming and stored in the predetermined recording medium is referred to, and inspection is performed with respect to only the chip regions that have not been determined to be non-conforming. As a result, each time inspection of the semiconductor wafer is performed, regions that have been determined to be non-conforming may be excluded from the inspection and thus, as manufacturing flow progresses, inspection throughput of the semiconductor wafer may be enhanced. The inspection throughput is enhanced, whereby facility investment may be suppressed.

Further, according to the embodiment, after the surface electrode is formed at the front surface of the semiconductor wafer but before annealing of the surface electrode, an automated visual inspection for detecting convex defects and concave defects of the surface electrode is performed by the visual inspection system. At this time, the exposure focus is aligned with the surface of the resist film on a normal portion of the surface electrode and a fine resist pattern is formed on the surface of the surface electrode, by photolithography and etching. The exposure focus is not aligned with the surfaces of the portions of the resist film on the convex defects and on the concave defects of surface electrode and thus, portions of the fine resist pattern on the convex defects and on the concave defects constitute the deficient pattern portions. The deficient pattern portions are detected by the visual inspection system, whereby convex defects and concave defects of the surface electrode may be detected.

Further, when convex defects and concave defects are detected by the visual inspection system, the focus is aligned with the surface of the fine resist pattern, whereby the focus ceases to be aligned with the grain boundaries of the surface electrode and thus, false detection of the grain boundaries by the visual inspection system do not occur. Defects detected by the visual inspection system do not have to be re-evaluated by a site-operator and thus, inspection throughput is further enhanced. Further, in the overall flow of manufacturing, labor for re-evaluation by manual visual inspection performed by a site-operator is reduced and thus, the load on a site-operator may be reduced. Further, the fine resist pattern is a pattern with regularity and thus, a deficient pattern portion of the resist pattern is easily detected by the visual inspection system and the inspection throughput is further enhanced.

Further, according to the embodiment, a chip region in which foreign matter is incorporated in the surface electrode and convex defects and concave defects occur may be reliably detected. Thus, for example, during the plating treatment on the surface of the surface electrode, when the plating solution permeates the layer below from convex and concave defects of the surface electrode, etc. and a semiconductor chip that is at a risk of having an electrical characteristics defect (assembly defect) in the reliability test during the assembly process, the semiconductor chip can be determined to be defective at the semiconductor wafer process stage and removed. Thus, defective modules and manufacturing costs may be reduced.

In the foregoing, the present disclosure is not limited to the embodiments described and various modifications within a range not departing from a range of the spirit of the disclosure are possible. For example, the present disclosure is applicable to various types of semiconductor devices, independent of the device structure, wafer size, material of the semiconductor wafer, etc.

The method of manufacturing the semiconductor device according to the present disclosure achieves an effect in that sensitivity of visual inspection may be enhanced.

As described, the method of manufacturing the semiconductor device according to the present disclosure is useful for power semiconductor devices used in power converting equipment, power source devices of various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A method of manufacturing a semiconductor device, the method comprising:
as a first process, preparing a semiconductor wafer and forming a surface electrode on a surface of the semiconductor wafer;
as a second process, forming a resist film on the surface electrode;
as third process, exposing and developing the resist film, thereby forming a resist pattern on the surface electrode; and
as a fourth process, detecting a surface defect occurring in the surface electrode during the first process, either
using a difference of intensities of lights reflected from the resist pattern on the surface electrode between an area thereof where the surface defect occurs and an area thereof where no surface defect occurs by irradiating light on the resist pattern on the surface electrode, or
using a comparison between a surface image of the area where the surface defect occurs and a surface image of the surface where no surface defect occurs by photographing the surface of the semiconductor wafer using a photographing mechanism, wherein
the third process includes causing a deficient pattern portion to occur in a portion of the resist pattern at the surface defect, and
the fourth process includes detecting a position of the deficient pattern portion at the resist pattern as a focal point of the lights irradiated or a focal point of the photographing mechanism, and determining a detected position of the deficient pattern portion as a detection position of the surface defect.

2. The method of manufacturing according to claim 1, wherein forming the resist pattern includes forming a plurality of resist left portions and a plurality of resist removed portions on the surface electrode without the defect, by setting each of the plurality of resist left portions to have smaller in size in a predetermined direction parallel to the surface of the semiconductor wafer than a width of the deficient pattern portion, or setting each of the plurality of resist removed portions to have smaller in size in the predetermined direction than a width of the deficient pattern portion.

3. The method of manufacturing according to claim 2, wherein
a width of the resist left portion of the resist pattern on the surface electrode without the defect in the predetermined direction is narrower than a width of the surface defect, and
the width of the resist removed portion of the resist pattern on the surface electrode without the defect is narrower than the width of the surface defect.

4. The method of manufacturing according to claim 2, wherein
a width of the resist left portion of the resist pattern on the surface electrode without the defect is not more than ¼ of the width of the surface defect, and
the width of the resist removed portion of the resist pattern on the surface electrode without the defect is not more than ¼ of the width of the surface defect.

5. The method of manufacturing according to claim 1, wherein the third process includes forming on the surface electrode without the defect, the resist pattern to have regularity or forming repeating patterns.

6. The method of manufacturing according to claim 1, wherein the third process includes forming the resist pattern in which a total area of the resist left portions is equal to a total area of the resist removed portions on the surface electrode without the defect.

7. The method of manufacturing according to claim 1, wherein
the surface defect includes a convex defect in which a portion of a surface of the surface electrode is raised, or a concave defect in which a portion of the surface of the surface electrode is recessed, or both the convex defect and the concave defect, and
the third process includes, setting, as a focal point of the exposing, a surface of a first portion of the resist film on the surface without the surface defect, and performing the exposing the resist film using light having a short wavelength so that the focal point of the exposing is not aligned with a surface of a second portion of the resist film on the surface defect to thereby form the resist pattern that has different patterns between the surface without the surface defect and the surface with the surface defect.

8. The method of manufacturing according to claim 7, wherein
the first process includes:
depositing the surface electrode by sputtering, and
patterning the surface electrode by photolithography and etching,
the convex defect occurs due to foreign matter being incorporated in the surface electrode during the depositing,
the concave defect occurs due to the surface electrode being selectively removed at a deficient resist portion of a resist mask used during the etching.

9. The method of manufacturing according to claim 1, wherein
the third process includes forming the resist pattern for each of a plurality of chip regions provided with regularity on the semiconductor wafer, and
the fourth process includes photographing the surface of the semiconductor wafer using the photographing mechanism and comparing images of two adjacent ones of the plurality of chip regions of the semiconductor wafer.
